(19) United States
(12) Patent Application Publication
(10) Pub. No.: US 2020/0202783 A1
(43) Pub. Date: Jun. 25, 2020

(54) PIXEL COMPENSATION CIRCUIT

(71) Applicant: INT TECH CO., LTD., Hsinchu County (TW)

(72) Inventor: SHIH-SONG CHENG, KAOHSIUNG CITY (TW)

(21) Appl. No.: 16/230,046

(22) Filed: Dec. 21, 2018

(51) Int. Cl. G09G 3/3258; G09G 3/3266; G09G 3/3291; H01L 27/32

(52) U.S. Cl. CPC G09G 3/3258; G09G 3/3266; G09G 3/3291; G09G 2300/0426; H01L 27/3265; G09G 2300/043; G09G 2320/0233; H01L 27/3262

(57) ABSTRACT

A pixel compensation circuit is arranged for compensating the critical parameter associated with the electrical properties of the components in thin film transistors of an active matrix organic light emitting diode display or similar illumination systems to avoid uneven brightness resulted from the voltage drop effect. The pixel compensation circuit is defined in a sub-pixel area, wherein there are seven thin film transistors and one capacitor, and the circuit is operated by two control signals. In contrast, three control signals are required in the conventional technologies. The fewer control signals are required, which is benefit to the flexibility of the layout and design of specification.

### BACKGROUND

Currently, an active matrix organic light emitting diode (AMOLED) display is the focus of the display field due to its amazing image quality and optical specification better than the conventional display.

The AMOLED display is used as an emitter with current through an organic light emitting diode, the current is controlled by an active matrix, and brightness of gray scale is determined by an amount of the current during light emission.

The active matrix is composed of a group of pixel units, and an effective area of light emission is defined by resolution. The effective area of light emission is an area of pixel units multiplied by a resolution in a vertical direction and then multiplied by a resolution in a horizontal direction.

A typical pixel unit is composed of three sub-pixel units. Generally, a sub-pixel unit is composed of a plurality of thin film transistors and capacitors, a gray scale of emission brightness of a sub-pixel area is controlled by the thin film transistor, and the capacitor is used as a storage potential to stabilize driving current.

However, in comparison with other displays (for example, liquid crystal displays), since the active matrix organic light emitting diode display has a characteristic of current driving light emission, the brightness difference of the gray scale can be directly affected by component electrical properties of the thin film transistor. When the thin film transistors in different sub-pixels have too much difference in component electrical properties, an uneven image property would be formed. For example, mura phenomenon occurs.

Therefore, to overcome the above problem, a pixel compensation circuit is formed to compensate parameters (threshold voltage Vth, for example) of electrical properties of critical components, so as to repair the deterioration of the image quality due to the difference between characteristics of the components.

In addition, another major problem occurring in the current driving system is the voltage drop (IR-drop) effect, which is generated when the distal voltage drop is caused by the electrical load of the system. The large output current corresponds to large electrical load, such that for an active matrix organic light emitting diode (AMOLED) display which is typically designed as a common power source, the brightness near the power source end is higher than the brightness away from the power source end. The issue of brightness uniformity can be overcome by a compensation circuit.

However, as the progressiveness of display technologies, there are more and more pixels in one unit size, a component size for displaying each pixel is correspondingly reduced. At least three signals are required in the conventional pixel compensation circuit, such that at least three signal generators or wirings are required, so as to limit the size reduction.

Accordingly, the conventional technologies have many drawbacks and need to be improved. Therefore, the present invention provides a pixel compensation circuit to improve brightness of an AMOLED and reduce the number of the required control signals.

### BRIEF SUMMARY OF THE INVENTION

The present invention relates to a pixel compensation circuit, and particularly, to a pixel compensation circuit for improving brightness uniformity of an active-matrix organic light emitting diode (AMOLED).

An aspect of the present invention provides a pixel compensation circuit. According to one embodiment of the present invention, the pixel compensation circuit includes an input module, a reset module, a data processing module and a switch module. The input module receives a reference level and a data signal, and generates a first signal in response to a light emission control signal and a scan signal. The reset module receives the reference level and generates a reset signal in response to a sub-light emission control signal and the scan signal. The data processing module receives the first signal, the reset signal and a first voltage, and generates a second signal in response to the scan signal. The switch module receives the second signal and generates a light emission signal in response to the light emission control signal.

The input module includes a first transistor, a sixth transistor and a storage capacitor. The first transistor includes a firs source terminal applied with the data signal, a first gate terminal applied with the scan signal, and a first drain terminal connected to a second node. The sixth transistor includes a sixth source terminal applied with the reference level, a sixth gate terminal applied with the light emission control signal and a sixth drain terminal connected to the second node. The storage capacitor includes a first electrode and a second electrode, the first electrode is connected to the second node, and the second electrode is connected to the data processing module.

Further, the data processing module includes a fourth transistor, and a second transistor. The fourth transistor includes a fourth source terminal applied with the first voltage, a fourth gate terminal connected to the input module and a fourth drain terminal connected to the switch module. The second transistor includes a second source terminal connected to the third node, a second gate terminal applied with the scan signal, and a second drain terminal connected to the fourth gate terminal.

In addition, the reset module includes a fifth transistor and a third transistor. The fifth transistor includes a fifth source terminal applied with the reference level, and a fifth gate terminal applied with a sub-light emission control signal. The third transistor includes a third source terminal connected to a fifth drain terminal of the fifth transistor, a third gate terminal applied with the scan signal, and a third drain terminal connected to the third node.

In the practical applications, when a plurality of pixel compensation circuits are connected in series to form a scat of pixel compensation circuits, the light emission control signal of an (N+1)th level pixel compensation circuit is used as the sub-light emission control signal of an Nth level pixel compensation circuit, and N is a positive integer.

The pixel compensation circuit further includes a light emitting component for receiving the light emission signal and then emitting light.

In comparison with the conventional technologies, the pixel compensation circuit of the present invention can be used for compensating the critical parameter, such as a threshold voltage Vₜₕ, associated with the electrical properties of the components in thin film transistors of an active matrix organic light emitting diode display or similar illumination systems, so as to improve the image quality and avoid uneven brightness resulted from the voltage drop (IR-drop) effect. The pixel compensation circuit of the present invention is defined in a sub-pixel area, wherein there are eight thin film transistors and one capacitor, and the circuit is operated by two control signals. In contrast, three control signals are required in the conventional technologies. The fewer control signals are required in the present invention, which is benefit to the flexibility of the layout and design of specification.

Advantages and spirit of the present disclosure are best understood from the following detailed description when read with the accompanying figures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view showing a pixel compensation circuit in accordance with an embodiment of the present invention.

FIG. 2 is a schematic view showing pixel compensation circuits of the present invention connected in series to a set of pixel compensation circuits.

FIG. 3 is a schematic view showing a display system using a pixel compensation circuit of the present invention.

FIG. 4 is a sequence diagram showing an operation of a pixel compensation circuit in accordance with an embodiment of the present invention.

FIG. 5 is a schematic diagram showing an operation of the pixel compensation circuit of FIG. 4 at a first timing.

FIG. 6 is a schematic diagram showing an operation of the pixel compensation circuit of FIG. 4 at a second timing.

FIG. 7 is a schematic diagram showing an operation of the pixel compensation circuit of FIG. 4 at a third timing.

### DETAILED DESCRIPTION

The present invention is described in detail with reference to the accompanying drawings that clearly illustrate objectives, technical solution and advantages of the present invention.

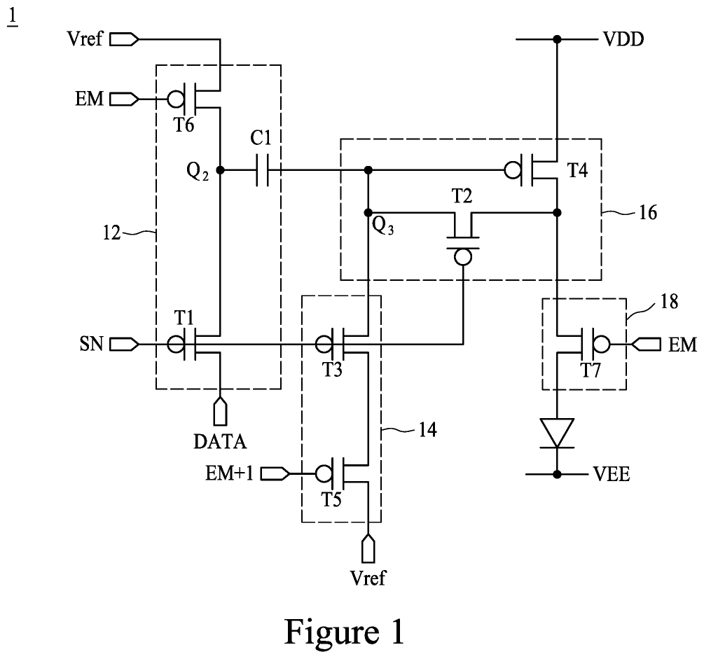

Please refer to FIG. 1, which is a schematic view showing a pixel compensation circuit according to an embodiment of the present invention. One aspect of the present invention provides a pixel compensation circuit (PCC) 1. According to one embodiment of the present invention, the pixel compensation circuit 1 includes an input module 12, a reset module 14, a data processing module 16 and a switch module 18. The input module 12 receives a reference level Vref and a data signal DATA, and responds to a light emission control signal EM and a scan signal SN, so as to produce a first signal. The reset module 14 receives the reference level Vref and responds to a sub-light emission control signal EM+1 and the scan signal SN, so as to produce a reset signal. The data processing module 16 receives the first signal, the reset signal and a first voltage VDD, and responds to the scan signal SN, so as to produce a second signal. The switch module 18 receives the second signal, and responds to the light emission control signal EM, so as to produce a light emission signal EM.

The sub-light emission control signal EM+1 is the light emission control signal EM with one line time shift.

The input module 12 includes a first transistor T₁, a sixth transistor T₆ and a storage capacitor C. The first transistor T₁ has a first source terminal applied with a data signal DATA, a first gate terminal applied with a scan signal SN, and a first drain terminal connected to a second node Q₂. The sixth transistor T₆ includes a sixth source terminal applied with a reference level Vref, a sixth gate terminal applied with a light emission control signal EM, and a sixth drain terminal connected to the second node Q₂. The storage capacitor C has a first electrode and a second electrode, the first electrode is connected to the second node Q₂, and the second electrode is connected to the data processing module 16.

The data processing module 16 includes a fourth transistor T₄, and a second transistor T₂. The fourth transistor T₄ has a fourth source terminal applied with a first voltage VDD, a fourth gate terminal connected to the input module 12, and a fourth drain terminal connected to the switch module 18. The second transistor T₂ has a second source terminal connected to the fourth drain terminal, a second gate terminal applied with a scan signal SN, and a second drain terminal connected to a third node Q₃.

The reset module 14 includes a fifth transistor T₅ and a third transistor T₃. The fifth transistor T₅ has a fifth source terminal applied with a reference level Vref, and a fifth gate terminal applied with a sub-light emission control signal EM+1. The third transistor T₃ has a third source terminal connected to a fifth drain terminal of the fifth transistor T₅, a third transistor T₃ gate terminal applied with a scan signal SN, and a third drain terminal connected to a third node Q₃.

The switch module 18 includes a seventh transistor T₇, which has a seventh source terminal connected to the data processing module 16, a seventh gate terminal applied with a light emission control signal EM, and a seventh drain terminal for outputting a light emission signal.

The pixel compensation circuit 1 further includes a light emitting component for receiving the light emission signal and then emitting light.

In practical applications, the light emitting component includes a first pole and a second pole. The first pole is used for receiving the light emission signal, and the second pole is connected to a second voltage VEE having a level different from that of the first voltage VDD.

In addition, the light emitting component can be an active-matrix organic light emitting diode (AMOLED).

In practical applications, the second voltage VEE can be obtained from being connected to the ground.

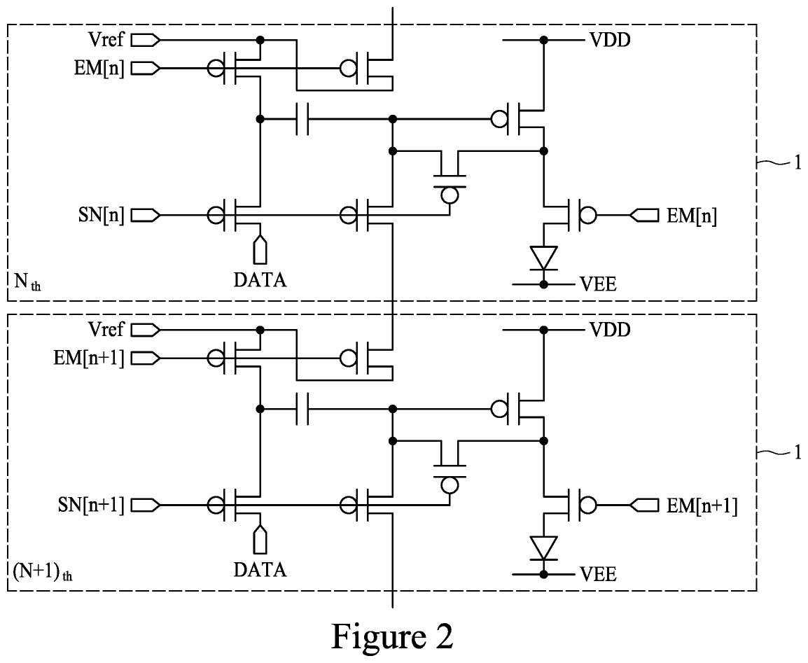

Please refer to FIG. 2, which is a schematic diagram showing the pixel compensation circuits 1 of the present invention connected in series to a set of pixel compensation circuits 1. In practical applications, when a plurality of pixel compensation circuits 1 are connected in series to form a set of pixel compensation circuits 1, a light emission control signal EM of an (N+1)th level pixel compensation circuit 1 can be used as a sub-light emission control signal EM+1 of an Nth level pixel compensation circuit 1, in which N is a positive integer.

Since the Nth level compensation circuit 1 can be used as the sub-light emission control signal EM+1 by being connected to the next-level light emission control signal EM+1, thereby reducing a needed signal generator and space occupied by wirings of the signal generator. Accordingly, in comparison with the typical pixel compensation circuit in which three control signals are required, the pixel compensation circuit 1 of the present invention only requires two control signals which is benefit to optimization of the layout.

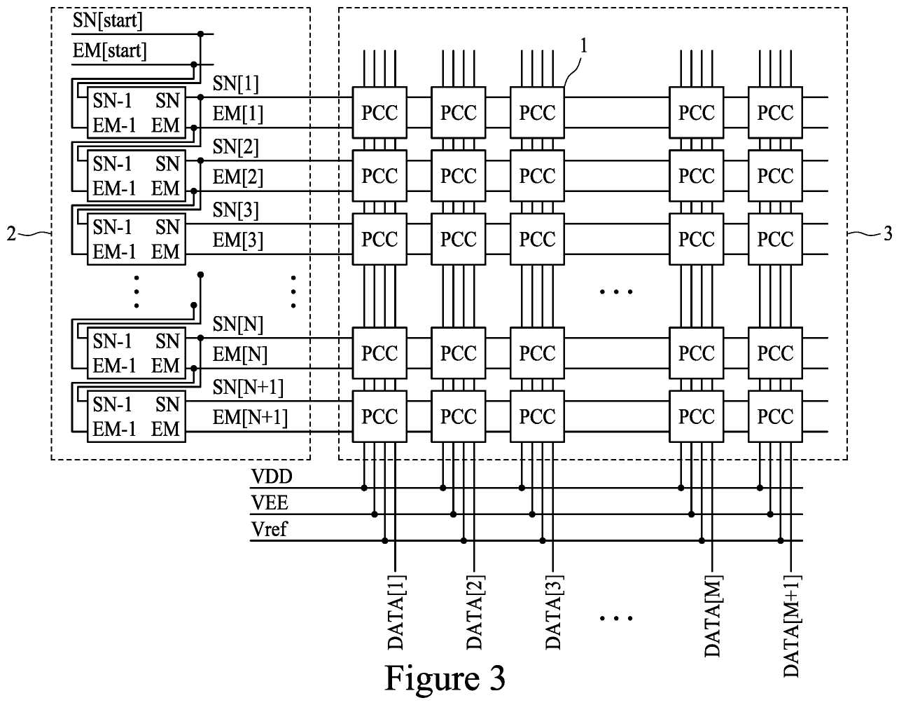

Please refer to FIG. 3, which is a schematic view showing a display system using the pixel compensation circuit 1 of the present invention. In one embodiment, a display system with [N+1]*[M+1] resolution can be divided into two areas, a gate driver on array (GOA) circuit area 2 and a display pixel circuit area 3, wherein the display pixel circuit area 3 is composed of a plurality of pixel compensation circuits 1 connected in series. A double of line time is used as a unit of time shift for the GOA circuit area 2 to scan delivery, and the GOA circuit 2 can be replaced by an integrated circuit IC with the same function. Each sub-pixel circuit in the display pixel circuit area 3 is the pixel compensation circuit 1 of the present invention, and is controlled and driven by the GOA circuit area 2. The operation is activated in a GOA scan direction and in a sequence of SN[1]→SN[2] . . . ′ EM[1]→EM[2]. . . . In FIG. 3, each pixel compensation circuit 1 only requires two control signals, and the wirings of the first voltage VDD, the second voltage VEE and the reference level Vref can be wound in a horizontal or vertical direction depending on space and manner of layout arrangements, thereby increasing flexibility of layout arrangements.

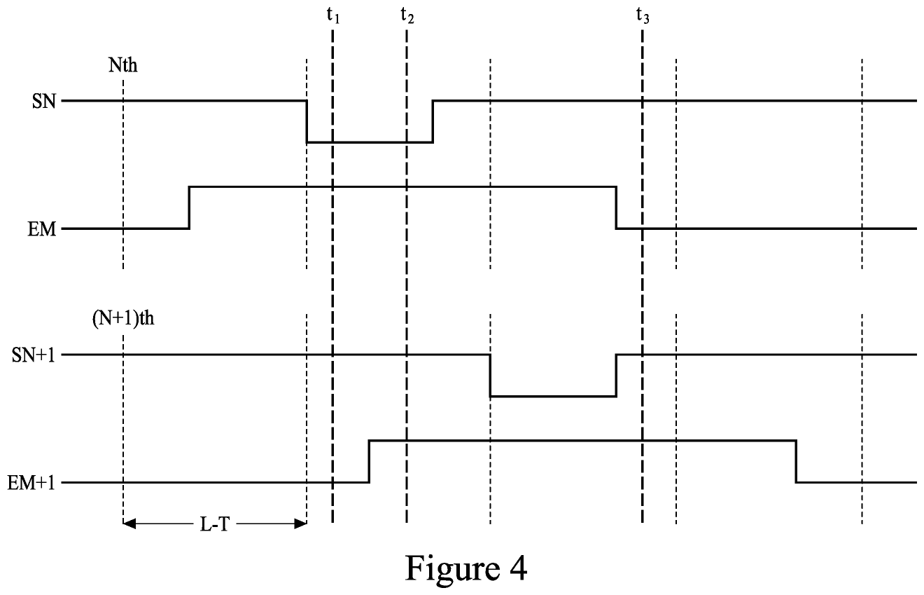

Please refer to FIG. 4, which is a sequence diagram showing an operation of the pixel compensation circuit 1 in accordance with an embodiment of the present invention. The operation sequence diagram of the compensation circuit 1 of the present invention is shown in FIG. 4, wherein please note that only the Nth level and the (N+1)th level light emission control signals EM, EM+2 and the scan signal SN, SN+1 are shown, and the light emission control signals EM, EM+1 and the scan signals SN, SN+2 respectively shift for one line time (L−T). For example, in the Nth level pixel compensation circuit 1, there are three stages while the pixel compensation circuit 1 works: a reset stage (a first timing t₁) a compensation stage (a second timing t₂) and a write light emission stage (a third timing t₃), which are described in detail in the following descriptions. In the following figures, a first node Q₁ is added to facilitate the descriptions, wherein the first node Q₁ is an electrical connection junction of the storage capacitor C, the second transistor T₂ and the fourth transistor T₄.

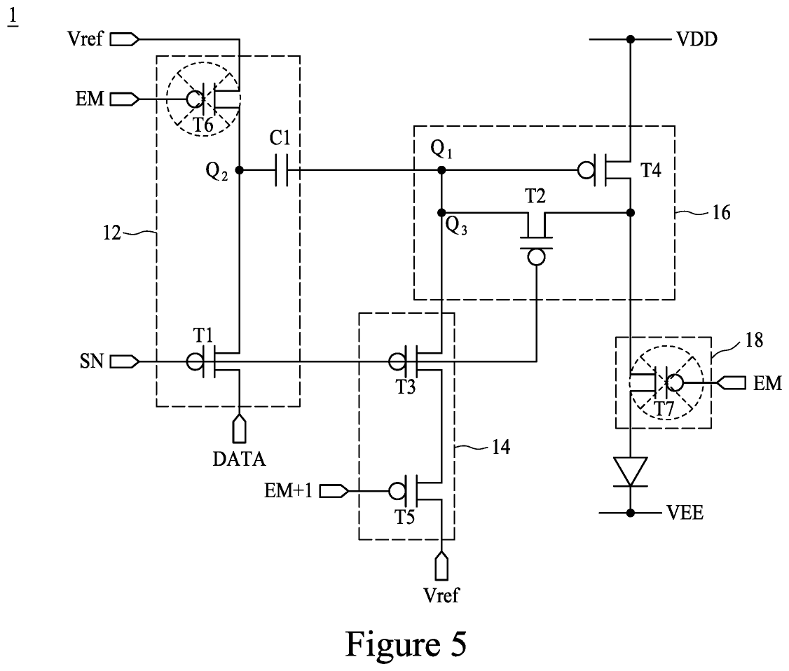

Please refer to FIG. 4 and FIG. 5. FIG. 5 is a schematic diagram showing an operation of the pixel compensation circuit of FIG. 4 at the first timing t₁. In the reset stage, due to the light emission control signal EM, the sixth transistor T₆ and the seventh transistor T₇ are turned off, and the remaining transistors are conducted. At this time, the signal of the first note Q₁ is the reference level Vref, the signal of the second node Q₂ is the data signal DATA, and the signal of the third node Q₃ is the reference level Vref.

At the same time, the gate potential V_{g} of the fourth transistor T₄ for driving is supplied by the first note Q₁ (Vref), the source potential Vₛ is supplied by the first voltage VDD, and V_{sg}=VDD−Vref>Vₜₕ is satisfied, wherein Vₜₕ is a threshold bias voltage.

Since two ends of the storage capacitor C are the reference level Vref supplied by the first node Q₁ and the data signal DATA supplied by the second node Q₂, the potential of the two ends of the storage capacitor C are reset.

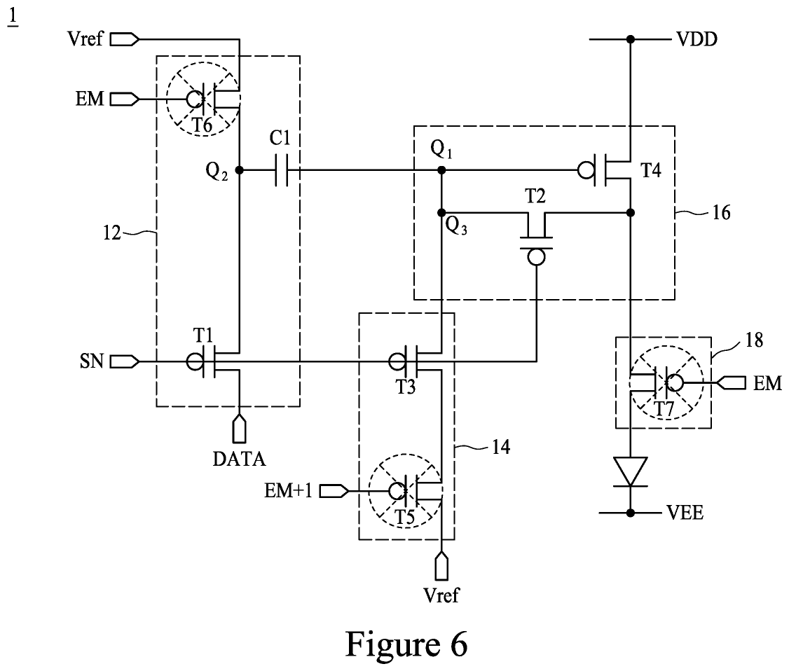

Please refer to FIG. 4 and FIG. 6. FIG. 6 is a schematic diagram showing an operation of the pixel compensation circuit 1 of FIG. 4 at the second timing t₂. In the compensation stage, due to the light emission control signal EM and the sub-light emission control signal EM+1, the fifth transistor T₅, the sixth transistor T₆ and the seventh transistor T₇ are turned off. At this time, the voltage at the first node Q₁ is changed from Vref to VDD−|Vₜₕ|, the second node Q₂ is kept as the previous status (DATA), and the voltage of the third node Q₃ is changed from Vref to VDD−|Vₜₕ|.

At this time, the gate potential V_{g} of the fourth transistor T₄ for driving is VDD−|Vₜₕ|, and the source potential Vₛ is VDD. The first node Q₁ is charged by VDD through the fourth transistor T₄ until pinch-off occurs in the fourth transistor T₆, thereby making V_{sg}=|Vₜₕ|.

Further, since the electrode potentials at two ends of the storage capacitor C are VDD−|Vₜₕ| and DATA, respectively, the potential difference between the two ends of the storage capacitor C is re-balanced.

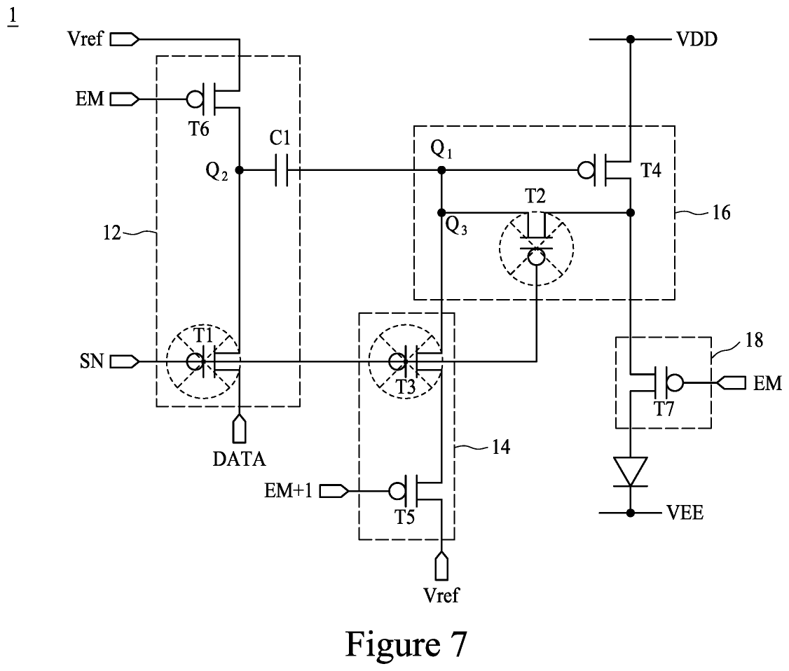

Please refer to FIG. 4 and FIG. 7. FIG. 7 is a schematic diagram showing an operation of the pixel compensation circuit 1 of FIG. 4 at the third timing t₃. In the write light emission stage, due to the scan signal SN, the first transistor T₁, the second transistor T₂, and the third transistor T₃ are turned off. At this time, the voltage at the first node Q₁ is changed from VDD−|Vₜₕ| to VDD−DATA+Vref−|Vₜₕ|, the voltage at the second node Q₂ is changed from DATA to Vref, and the third node Q₃ is kept as the previous status (VDD−|Vₜₕ|).

At this time, the gate potential of the fourth transistor T₄ for driving is VDD−DATA+Vref−|Vth|, and the source potential Vₛ is VDD. The potential change of the second node Q₂ causes that the first node Q₁ writes the DATA value due to the coupling effect of the storage capacitor, making V_{sg}=DATA−Vref+|Vₜₕ|.

At this time, the operation of this stage would not affected by turn-on or turn-off of the fifth transistor T₅.

After compensation, the current for driving the transistor is expressed in the following equation.

|I_{sd}|= [symbol] *(|V_{sg}|−|Vₜₕ|)²= [symbol] *(DATA−Vref)²

There is no Vth and VDD in the above equation, such that the threshold bias voltage Vₜₕ is compensated and the voltage drop (IR-drop) effect is improved.

Accordingly, the pixel compensation circuit 1 of the present invention can be applied in an active matrix organic light emitting diode display so as to compensate the threshold bias voltage Vₜₕ of the thin film transistor and avoid image deterioration, such as Mura, resulted from the difference of electrical properties between the components. At the same time, the voltage drop (IR-drop) resulted from the distribution of the system power can be compensated so as to improve brightness of the panel while the display is illuminated.

In comparison with the conventional technologies, the pixel compensation circuit of the present invention can be used for compensating the critical parameter, such as a threshold voltage Vₜₕ, associated with the electrical properties of the components in thin film transistors of an active matrix organic light emitting diode display or similar illumination systems, so as to improve the image quality and avoid uneven brightness resulted from the voltage drop (IR-drop) effect. The pixel compensation circuit of the present invention is defined in a sub-pixel area, wherein there are eight thin film transistors and one capacitor, and the circuit is operated by two control signals. In contrast, three control signals are required in the conventional technologies. The fewer control signals are required in the present invention, which is benefit to the flexibility of the layout and design of specification.

The features and scope of the present invention is clearly described, but not limited by, the illustrations of the above embodiments. Furthermore, the various changes and equivalent arrangements are covered by the scope of claims of the present invention.

What is claimed is:

1. A pixel compensation circuit, comprising:
an input module, receiving a reference level and a data signal and generating a first signal in response to a light emission control signal and a scan signal;
a reset module, receiving the reference level and generating a reset signal in response to a sub-light emission control signal and the scan signal, wherein the sub-light emission control signal and the light emission control signal shift for one line time;
a data processing module, receiving the first signal, the reset signal and a first voltage, and generating a second signal in response to the scan signal; and
a switch module, receiving the second signal and generating a light emission signal in response to the light emission control signal,
wherein the reset module includes a third transistor and the data processing module includes a fourth transistor, wherein a drain terminal of the third transistor is connected to a gate terminal of the fourth transistor.

2. The pixel compensation circuit of claim 1, wherein the input module comprises:
a first transistor, having a first source terminal applied with the data signal, a first gate terminal applied with the scan signal, and a first drain terminal connected to a second node;
a sixth transistor, having a sixth source terminal applied with the reference level, a sixth gate terminal applied with the light emission control signal, and a sixth drain terminal connected to the second node; and
a storage capacitor, having a first electrode and a second electrode, wherein the first electrode is connected to the second node, and the second electrode is connected to the data processing module.

3. The pixel compensation circuit of claim 1, wherein the data processing module further comprises:
a second transistor, having a second source terminal connected to the drain terminal, a second gate terminal applied with the scan signal, and a second drain terminal connected to a third node,
wherein the fourth transistor has a fourth source terminal applied with the first voltage, the gate terminal connected to the input module, and the drain terminal connected to the switch module.

4. The pixel compensation circuit of claim 3, wherein the reset module further comprises:
a fifth transistor, having a fifth source terminal applied with the reference level, and a fifth gate terminal applied with a sub-light emission control signal,
wherein the third transistor has a third source terminal connected to a fifth drain terminal of the fifth transistor, a third gate terminal applied with the scan signal, and the drain terminal connected to the third node.

5. The pixel compensation circuit of claim 1, wherein the switch module comprises:
a seventh transistor, having a seventh source terminal connected to the data processing module, a seventh gate terminal applied with the light emission control signal, and a seventh drain terminal for outputting the light emission signal.

6. The pixel compensation circuit of claim 1, wherein when a plurality of the pixel compensation circuits are connected in series to form a set of pixel compensation circuits, the light emission control signal of an (N+1)th level pixel compensation circuit is used as the sub-light emission control signal of an Nth level pixel compensation circuit, and N is a positive integer.

7. An active-matrix organic light emitting diode display, comprises:
a pixel compensation circuit, comprising:
an input module, receiving a reference level and a data signal and generating a first signal in response to a light emission control signal and a scan signal;
a reset module, receiving the reference level and generating a reset signal in response to a sub-light emission control signal and the scan signal, wherein the sub-light emission control signal and the light emission control signal shift for one line time;
a data processing module, receiving the first signal, the reset signal and a first voltage, and generating a second signal in response to the scan signal; and
a switch module, receiving the second signal and generating a light emission signal in response to the light emission control signal,
wherein the reset module includes a third transistor and the data processing module includes a fourth transistor, wherein a drain terminal of the third transistor is connected to a gate terminal of the fourth transistor.

8. The active-matrix organic light emitting diode display of claim 7, wherein the input module comprises:
a first transistor, having a first source terminal applied with the data signal, a first gate terminal applied with the scan signal, and a first drain terminal connected to a second node;
a sixth transistor, having a seventh source terminal applied with the reference level, a sixth gate terminal applied with the light emission control signal, and a sixth drain terminal connected to the second node; and
a storage capacitor, having a first electrode and a second electrode, wherein the first electrode is connected to the second node, and the second electrode is connected to the data processing module.

9. The active-matrix organic light emitting diode display of claim 7, wherein the data processing module comprises:
a second transistor, having a second source terminal connected to the drain terminal, a second gate terminal applied with the scan signal, and a second drain terminal connected to a third node,
wherein the fourth transistor has a fourth source terminal applied with the first voltage, the gate terminal connected to the input module, and the drain terminal connected to the switch module.

10. The active-matrix organic light emitting diode display of claim 9, wherein the reset module comprises:
a fifth transistor, having a fifth source terminal applied with the reference level, and a fifth gate terminal applied with a sub-light emission control signal,
wherein the third transistor has a third source terminal connected to a fifth drain terminal of the fifth transistor, a third gate terminal applied with the scan signal, and the drain terminal connected to the third node.

11. The active-matrix organic light emitting diode display of claim 7, wherein the switch module comprises:
a seventh transistor, having a seventh source terminal connected to the data processing module, a seventh gate terminal applied with the light emission control signal, and a seventh drain terminal for outputting the light emission signal.

12. The active-matrix organic light emitting diode display of claim 7, wherein when a plurality of the pixel compensation circuits are connected in series to form a set of pixel compensation circuits, the light emission control signal of an (N+1)th level pixel compensation circuit is used as the sub-light emission control signal of an Nth level pixel compensation circuit, and N is a positive integer.

13. The active-matrix organic light emitting diode display of claim 7, wherein the pixel compensation circuit further includes a light emitting component, the light emitting component has a first pole and a second pole, the first pole is used for receiving the light emission signal, and the second pole is connected to a second voltage having a level different from that of the first voltage.

14. A display system, comprising:
a pixel compensation circuit, comprising:
an input module, receiving a reference level and a data signal and generating a first signal in response to a light emission control signal and a scan signal;
a reset module, receiving the reference level and generating a reset signal in response to a sub-light emission control signal and the scan signal, wherein the sub-light emission control signal and the light emission control signal shift for one line time;
a data processing module, receiving the first signal, the reset signal and a first voltage, and generating a second signal in response to the scan signal; and
a switch module, receiving the second signal and generating a light emission signal in response to the light emission control signal,
wherein the reset module includes a third transistor and the data processing module includes a fourth transistor, wherein a drain terminal of the third transistor is connected to a gate terminal of the fourth transistor.

15. The display system of claim 14, wherein the input module comprises:
a first transistor, having a first source terminal applied with the data signal, a first gate terminal applied with the scan signal, and a first drain terminal connected to a second node;
a sixth transistor, having a seventh source terminal applied with the reference level, a sixth gate terminal applied with the light emission control signal, and a sixth drain terminal connected to the second node; and
a storage capacitor, having a first electrode and a second electrode, wherein the first electrode is connected to the second node, and the second electrode is connected to the data processing module.

16. The display system of claim 14, wherein the data processing module comprises:
a second transistor, having a second source terminal connected to the drain terminal, a second gate terminal applied with the scan signal, and a second drain terminal connected to a third node,
wherein the fourth transistor has a fourth source terminal applied with the first voltage, the gate terminal connected to the input module, and the drain terminal connected to the switch module.

17. The display system of claim 16, wherein the reset module comprises:
a fifth transistor, having a fifth source terminal applied with the reference level, and a fifth gate terminal applied with a sub-light emission control signal,
wherein the third transistor has a third source terminal connected to a fifth drain terminal of the fifth transistor, a third gate terminal applied with the scan signal, and the drain terminal connected to the third node.

18. The display system of claim 14, wherein the switch module comprises:
a seventh transistor, having a seventh source terminal connected to the data processing module, a seventh gate terminal applied with the light emission control signal, and a seventh drain terminal for outputting the light emission signal.

19. The display system of claim 14, wherein when a plurality of the pixel compensation circuits are connected in series to form a set of pixel compensation circuits, the light emission control signal of an (N+1)th level pixel compensation circuit is used as the sub-light emission control signal of an Nth level pixel compensation circuit, and N is a positive integer.

20. The display system of claim 14, further comprising a display pixel circuit area composed of a plurality of the pixel compensation circuits connected in series and in parallel.
